(19) United States
(12) Patent Application Publication
(10) Pub. No.: US 2021/0011195 A1
(43) Pub. Date: Jan. 14, 2021

(54) TERAHERTZ METAMATERIAL

(71) Applicants: KUANG-CHI INNOVATIVE TECHNOLOGY LTD., Shenzhen (CN); KUANG-CHI INSTITUTE OF ADVANCED TECHNOLOGY, Shenzhen (CN)

(72) Inventors: Ruopeng Liu, SHENZHEN (CN); Wei Xiong, SHENZHEN (CN); Jincai Ye, SHENZHEN (CN); Jiawei He, SHENZHEN (CN); Jinjin Wang, SHENZHEN (CN); Jiangbo Chen, SHENZHEN (CN); Shuyuan Zhang, SHENZHEN (CN)

(21) Appl. No.: 17/033,436

(22) Filed: Sep. 25, 2020

Related U.S. Application Data
(62) Division of application No. 15/894,017, filed on Feb. 12, 2018.

(30) Foreign Application Priority Data
Aug. 20, 2015 (CN) 201510514703.0

(51) Int. Cl. G02B 1/00; C09K 3/00; B82Y 30/00; C01B 3/02; H05K 9/00; H01Q 17/00; C08J 7/04; C08K 3/04; G02B 26/00; H01Q 1/36; H01Q 7/00

(52) U.S. Cl. CPC G02B 1/002; C09K 3/00; B82Y 30/00; C01B 3/02; H05K 9/00; H01Q 17/00; C08K 2201/011; C08K 3/04; G02B 26/007; H01Q 1/368; H01Q 7/00; C08J 2379/08; C08J 7/0427

(57) ABSTRACT

The present invention discloses a terahertz metamaterial. The terahertz metamaterial includes a substrate and an electromagnetic loss resonant ring structure disposed on the substrate, where an electromagnetic modulation function is realized on a terahertz band by adjusting different structural sizes and square resistance of the electromagnetic loss resonant ring structure. In the present invention, the electromagnetic loss resonant ring structure is disposed on the substrate, and the electromagnetic modulation function is realized on the terahertz band by adjusting the different structural sizes and square resistance of the electromagnetic loss resonant ring structure, thereby simplifying processing steps of a terahertz device, reducing a processing cost, and enabling a terahertz technology to be widely used in the field of electromagnetic communication.

### CROSS-REFERENCE TO RELATED APPLICATIONS

The present disclosure is a divisional application of U.S. patent application Ser. No. 15/894,017, filed Feb. 12, 2018, which is a National Stage entry of PCT/CN2016/095805 filed Aug. 18, 2016, which claims priority to Chinese Patent Application No. 201510514703.0, filed Aug. 20, 2015, the entire contents of which are hereby entered in their entirety herein.

### TECHNICAL FIELD

The present invention relates to the field of electromagnetic communications, and specifically, to a terahertz metamaterial.

### BACKGROUND

The terahertz band (Terahertz, THz) refers to an electromagnetic wave whose frequency is in a range of 0.1 THz to 10 THz, a wavelength of the terahertz band covers 3 mm to 30 μm, and the terahertz band is also called THz radiation, a sub-millimeter wave, or a T-ray. The terahertz band is between a millimeter wave and an infrared wave in an electromagnetic spectrum, and is not widely used in the field of electromagnetic communications when compared with the two bands: the millimeter wave and the infrared wave.

For a reason of limited application of the terahertz band, mainly being constrained by a terahertz generating source, a detector, and a functional device, the terahertz band has not yet been used on a large scale. In addition, because a terahertz wavelength is very short, a terahertz device has a much smaller size when compared with a microwave device. That is, the size of the terahertz device may be on an order of a few percents of a size of the microwave device. Therefore, it is very difficult to process the terahertz device, and a cost is high.

Therefore, in the prior art, most of the terahertz devices are obtained by using a photolithography method. However, this causes problems of a small sample size and a low yield rate, and this obviously constrains in-depth research and wide application of a terahertz technology greatly.

For problems in the prior art of being difficult to process a terahertz device, an expensive price, and being adverse to application of a terahertz technology in the field of electromagnetic communications, currently, no effective solution is yet proposed.

### SUMMARY

To resolve the foregoing problems in the prior art, the present invention proposes a terahertz metamaterial, which can simplify processing steps of a terahertz device, reduce a processing cost, and can be widely used in the field of electromagnetic communications.

The technical solutions of the present invention are realized in this way:

According to one aspect of the present invention, a terahertz metamaterial is provided.

The terahertz metamaterial includes:

a substrate; and

an electromagnetic loss resonant ring structure disposed on the substrate, where an electromagnetic modulation function is realized on a terahertz band by adjusting different structural sizes and square resistance of the electromagnetic loss resonant ring structure.

The substrate includes a flexible substrate.

In addition, the terahertz metamaterial further includes:

an electromagnetic loss film covering the substrate.

The foregoing electromagnetic loss resonant ring structures of different sizes are processed on the electromagnetic loss film.

Optionally, the electromagnetic loss resonant ring structure is a resonant ring structure that has an opening.

The resonant ring structure that has an opening is U-shaped, V-shaped, C-shaped, inverted h-shaped, L-shaped, or y-shaped.

Optionally, the electromagnetic loss resonant ring structure is a closed resonant ring structure.

The closed resonant ring structure is elliptical, closed polygonal, D-shaped, or P-shaped.

Optionally, the square resistance of the electromagnetic loss resonant ring structure is 200 ohms per square.

In addition, a material included in the electromagnetic loss film is selected from nano-carbon powder, resin, or a combination of nano-carbon powder and resin.

In addition, optionally, a plurality of electromagnetic loss resonant ring structures are disposed on the substrate, and the plurality of electromagnetic loss resonant ring structures are arranged on the substrate in a periodical array manner.

The substrate is divided into a plurality of cells, and one electromagnetic loss resonant ring structure is placed on each cell.

Preferably, the cell is square, and size ranges of a length and a width of the cell are both between 320 μm to 480 μm.

Preferably, the flexible substrate includes a polyimide(PI) film.

Preferably, the flexible substrate is a substrate with a low dielectric constant.

Optionally, a value range of a dielectric constant of the substrate is between 2.8 to 4.2, a value range of a loss angle tangent of the substrate is between 0.0048 to 0.0072, and a value range of a thickness of the substrate is between 60 μm to 90 μm.

Optionally, a value range of a dielectric constant of the substrate is between 3.44 to 5.16, a value range of a loss angle tangent of the substrate is between 0.0032 to 0.0048, and a value range of a thickness of the substrate is between 32 μm to 48 μm.

A factor of the terahertz metamaterial that affects the electromagnetic modulation function on the terahertz band includes at least one of the following:

a size of the electromagnetic loss resonant ring structure;

square resistance of the electromagnetic loss resonant ring structure; or

a periodical arrangement manner of the plurality of electromagnetic loss resonant ring structures on the substrate.

Preferably, the electromagnetic loss resonant ring structure includes two side edges that are parallel and symmetrical to each other and a bottom edge that connects the two side edges.

Preferably, a value range of a length of the side edge is between 180 μm to 220 μm, a value range of a width of the side edge is between 40 μm to 60 μm, a distance between the two side edges is between 180 μm to 220 μm, and a value range of a length of the bottom edge is between 240 μm to 360 μm.

In the present invention, an electromagnetic loss resonant ring structure is disposed on a substrate, and an electromagnetic modulation function is realized on a terahertz band by adjusting different structural sizes and square resistance of the electromagnetic loss resonant ring structure, thereby simplifying processing steps of a terahertz device, reducing a processing cost, and enabling a terahertz technology to be widely used in the field of electromagnetic communications.

### BRIEF DESCRIPTION OF DRAWINGS

To describe the technical solutions in the embodiments of the present invention or in the prior art more clearly, the following briefly introduces the accompanying drawings required for describing the embodiments. Apparently, the accompanying drawings in the following description show merely some embodiments of the present invention, and a person of ordinary skill in the art may still derive other drawings from these accompanying drawings without creative efforts.

FIG. 1 is a side view of a terahertz metamaterial according to an embodiment of the present invention; and

FIG. 2 is a top view of the terahertz metamaterial shown in FIG. 1.

### DESCRIPTION OF EMBODIMENTS

The following clearly and completely describes the technical solutions in the embodiments of the present invention with reference to the accompanying drawings in the embodiments of the present invention. Apparently, the described embodiments are merely a part rather than all of the embodiments of the present invention. All other embodiments obtained by a person of ordinary skill in the art based on the embodiments of the present invention shall fall within the protection scope of the present invention.

According to an embodiment of the present invention, a terahertz metamaterial is provided.

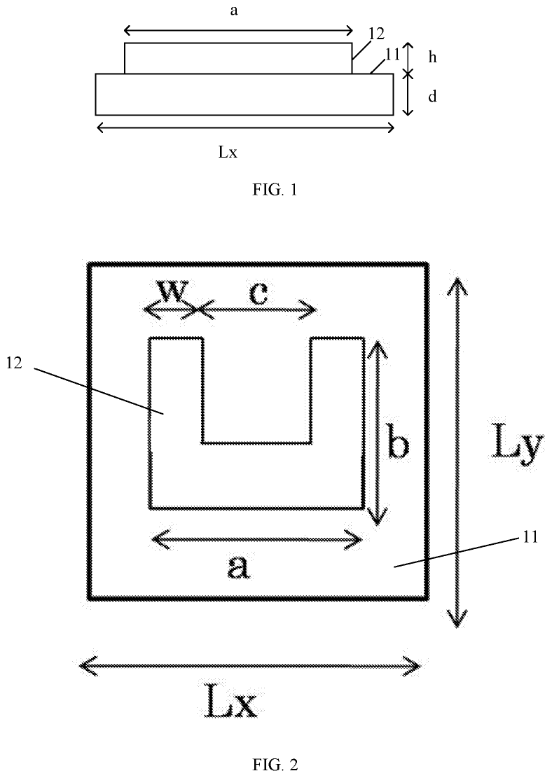

As shown in FIG. 1, the terahertz metamaterial according to the embodiment of the present invention includes:

a substrate 11, and an electromagnetic loss resonant ring structure 12 disposed on an upper surface of the substrate 11, where it can be seen from FIG. 2, which is a top view of the terahertz metamaterial and corresponds to FIG. 1, that, the electromagnetic loss resonant ring structure 12 is a ring structure, and an electromagnetic modulation function can be realized on a terahertz band by adjusting different structural sizes and square resistance of the electromagnetic loss resonant ring structure 12.

For the electromagnetic loss resonant ring structure 12 in the foregoing embodiment, in a production process of the terahertz metamaterial, first, it is necessary to cover an electromagnetic loss film on the substrate 11, and the electromagnetic loss resonant ring structure 12 is processed and made based on the electromagnetic loss film. In a different embodiment, the electromagnetic loss resonant ring structures 12 of different sizes may be processed on the electromagnetic loss film, so that a plurality of electromagnetic loss resonant ring structures of different sizes are disposed on the substrate.

It can be seen from the embodiments shown in FIG. 1 and FIG. 2 that, the electromagnetic loss resonant ring structure according to the embodiment of the present invention may be a resonant ring structure that has an opening (FIG. 1 and FIG. 2 illustrate a regular resonant ring that has a single opening), but according to a different requirement for electromagnetic modulation, the electromagnetic loss resonant ring structure 12 may also be constructed to be a closed resonant ring structure or a resonant ring structure that has a plurality of openings, so as to adjust a frequency and an amplitude of electromagnetic loss of the terahertz band (0.1 THz to 10 THz).

For example, in a different embodiment, when the electromagnetic loss resonant ring structure is a resonant ring structure that has an opening, the resonant ring structure that has an opening may be U-shaped, V-shaped, C-shaped, inverted h-shaped, L-shaped, y-shaped, or the like.

When the electromagnetic loss resonant ring structure is a closed resonant ring structure, the closed resonant ring structure may be elliptical, closed polygonal, D-shaped, P-shaped, or the like.

Preferably, it can be seen from FIG. 2 that, in this embodiment, the resonant ring structure is a U-shaped regular resonant ring that has a single opening (that is, a single-opening square resonant ring). It can be seen from FIG. 1 that, the single-opening square resonant ring includes two side edges that are parallel and symmetrical to each other and a bottom edge that connects the two side edges. For sizes of the two side edges and the bottom edge, a value range of a length of the side edge herein is between 180 μm to 220 μm, a value range of a width of the side edge is between 40 μm to 60 μm, a value range of a distance between the two side edges is between 180 μm to 220 μm, and a value range of a length of the bottom edge is between 240 μm to 360 μm. In a preferred embodiment, the length and the width of the side edge are, respectively, 200 μm and 50 μm, the distance between the two side edges is 200 μm, and the length of the bottom edge is 300 μm.

Correspondingly, it can be further seen from FIG. 2 that, a thickness h of the electromagnetic loss resonant ring structures 12 is 18 μm.

The square resistance of the electromagnetic loss resonant ring structure shown in FIG. 2 is 200 ohms per square.

Certainly, just an illustrative example is provided herein. That is, the present invention does not limit a specific shape of a resonant ring structure, as long as the electromagnetic loss resonant ring structure is made to be a ring structure, so that a ring structure of a different type can be set according to a different modulation requirement for the terahertz band.

In addition, in one embodiment, for a composition material of the electromagnetic loss film of the foregoing processed electromagnetic loss resonant ring structure, the included material is selected from nano-carbon powder, resin, or a combination of nano-carbon powder and resin. That is, the electromagnetic loss film may be made of nano-scale carbon powder, may be made of a resin material, or may be made of a mixture material with nano-scale carbon powder and resin material doped together. Certainly, the composition material of the electromagnetic loss film may also be some other non-metallic materials with an electromagnetic loss function, so that a different non-metallic material can be doped according to a different modulation requirement for the terahertz band.

In the foregoing embodiment, one substrate being disposed with one electromagnetic loss resonant ring structure is used as an example. However, in essence, in a different embodiment, electromagnetic loss resonant ring structures 12 of different sizes may be processed on an electromagnetic loss film, so that a plurality of electromagnetic loss resonant ring structures of different sizes are disposed on a substrate.

Preferably, to achieve electromagnetic modulation on the terahertz band, the electromagnetic loss resonant ring structure 12 according to an embodiment of the present invention is arranged on a flexible substrate 11 in a periodical array manner. That is, a terahertz metamaterial according to an embodiment of the present invention may include a plurality of metamaterial unit structures that are shown in FIG. 2 and are arranged in the periodical array manner.

In an embodiment, when there are a plurality of electromagnetic loss resonant ring structures, a substrate may be divided into a plurality of cells, one electromagnetic loss resonant ring structure is placed on each cell, and a shape of an electromagnetic loss resonant ring structure placed on each cell may be the same or different.

In addition, it can be seen from FIG. 1 and FIG. 2 that, because the resonant ring structure in this embodiment is a square resonant ring, accordingly, a size of the flexible substrate 11 is designed to be a square structure, and size ranges of a length and a width of the flexible substrate 11 are both between 320 μm to 480 μm. In this embodiment, a preferred length Lx of the flexible substrate 11 is 400 μm, a preferred width Ly is 400 μm, and a size of the upper surface of the flexible substrate 11 may accommodate a resonant ring structure, so that an interval of space exists between the resonant ring structure and an edge of the flexible substrate.

In addition, in an embodiment, to enable the terahertz metamaterial in the present invention to realize electromagnetic modulation on the terahertz band, a substrate 11 according to an embodiment of the present invention may be a flexible substrate and a substrate with a low dielectric constant (the dielectric constant is less than 4.5 but greater than 3.8). For a composition component of the flexible substrate 11, the composition component may be a PI film. Certainly, the composition component may also be made of another flexible material. In this way, the terahertz metamaterial in the present invention can be attached to any curved surface, so that the terahertz metamaterial in the present invention is applied to a wider range of components, is not limited by a shape of a component, and has more universality of application.

In addition, in an embodiment, a terahertz metamaterial according to an embodiment of the present invention further provides two flexible substrates with different toughness. In an embodiment, a value range of a dielectric constant of the flexible substrate is between 2.8 to 4.2, a value range of a loss angle tangent of the flexible substrate is between 0.0048 to 0.0072, and a value range of a thickness of the flexible substrate is between 60 μm to 90 μm. In a preferred embodiment, a dielectric constant of the flexible substrate is 3.5, a loss angle tangent of the flexible substrate is 0.006, and it can be seen from FIG. 1 and FIG. 2 that a thickness d of the flexible substrate is 75 μm.

However, in another embodiment, a dielectric constant of a flexible substrate can also be in a range of between 3.44 to 5.16, a value range of a loss angle tangent of the flexible substrate is between 0.0032 to 0.0048, and a value range of a thickness of the flexible substrate is between 32 μm to 48 μm. In a preferred embodiment, a dielectric constant of the flexible substrate is 4.3, a loss angle tangent of the flexible substrate is 0.004, and it can be seen from FIG. 1 and FIG. 2 that a thickness d of the flexible substrate is 40 μm.

In this way, according to a different requirement of a manufactured electromagnetic component, a terahertz metamaterial in the present invention can have different toughness, so that an application environment of the terahertz metamaterial in the present invention is more extensive.

In addition, when a terahertz metamaterial in the present invention performs electromagnetic modulation on the terahertz band (0.1 THz to 10 THz), a factor affecting the electromagnetic modulation function of the terahertz metamaterial may be a size of the electromagnetic loss resonant ring structure 12 (for example, an opening status of a resonant ring, and a specific shape size), may be square resistance of the electromagnetic loss resonant ring structure 12, may also be a periodical arrangement manner of a plurality of the electromagnetic loss resonant ring structures 12 on the substrate 11 (that is, a different periodical arrangement manner), and certainly may also be any combination of the foregoing three factors. That is, the terahertz metamaterial according to the present invention can adjust a frequency and an amplitude of electromagnetic loss of the terahertz band by adjusting the resonant ring structure, square resistance of a non-metallic electromagnetic loss film that constitutes the resonant ring structure, and the arrangement manner of the resonant ring structure on a flexible substrate, thereby realizing electromagnetic adjustment.

In conclusion, by means of the foregoing technical solutions of the present invention, by disposing a resonant ring structure of a different size on an electromagnetic loss material, a metamaterial with a tuning electromagnetic feature is realized, so that a terahertz metamaterial that is based on an electromagnetic loss resonant ring structure in the present invention has advantages of a light weight, a low cost, and being easy to process. Compared with design of a terahertz metamaterial formed by an electromagnetic loss material that does not have any structure design, design of the terahertz metamaterial that is based on the electromagnetic loss resonant ring structure in the present invention has an advantage of adjustable loss, can control electromagnetic modulation on the terahertz band, and has more actual application values.

The foregoing descriptions are merely exemplary embodiments of the present invention, but are not intended to limit the present invention. Any modification, equivalent replacement, and improvement made without departing from the spirit and principle of the present invention shall fall within the protection scope of the present invention.

What is claimed is:

1. A processing method of a terahertz metamaterial, comprising:
covering an electromagnetic loss film on a substrate;
processing the electromagnetic loss film to obtain a plurality of electromagnetic loss resonant ring structures of different sizes;
wherein an electromagnetic modulation function is realized on a terahertz band by adjusting different structural sizes and square resistance of the electromagnetic loss resonant ring structure, wherein the substrate comprises a flexible substrate, and a material incorporated in the electromagnetic loss film is selected from nano-carbon powder, resin, or a combination of nano-carbon powder and resin.

2. The processing method of the terahertz metamaterial according to claim 1, wherein the electromagnetic loss resonant ring structure is a resonant ring structure that has an opening.

3. The processing method of the terahertz metamaterial according to claim 2, wherein the resonant ring structure that has an opening is U-shaped, V-shaped, C-shaped, inverted h-shaped, L-shaped, or y-shaped.

4. The processing method of the terahertz metamaterial according to claim 1, wherein the electromagnetic loss resonant ring structure is a closed resonant ring structure.

5. The processing method of the terahertz metamaterial according to claim 4, wherein the closed resonant ring structure is elliptical, closed polygonal, D-shaped, or P-shaped.

6. The processing method of the terahertz metamaterial according to claim 1, wherein the square resistance of the electromagnetic loss resonant ring structure is 200 ohms per square.

7. The processing method of the terahertz metamaterial according to claim 1, wherein a material comprised in the electromagnetic loss film is selected from nano-carbon powder, resin, or a combination of nano-carbon powder and resin.

8. The processing method of the terahertz metamaterial according to claim 1, wherein a plurality of electromagnetic loss resonant ring structures are disposed on the substrate, and the plurality of electromagnetic loss resonant ring structures are arranged on the substrate in a periodical array manner.

9. The processing method of the terahertz metamaterial according to claim 8, wherein the substrate is divided into a plurality of cells, and one electromagnetic loss resonant ring structure is placed on each cell.

10. The processing method of the terahertz metamaterial according to claim 9, wherein the cell is square, and size ranges of a length and a width of the cell are both between 320 μm to 480 μm.

11. The processing method of the terahertz metamaterial according to claim 1, wherein the flexible substrate comprises a polyimide film.

12. The processing method of the terahertz metamaterial according to claim 1, wherein the flexible substrate is a substrate with a low dielectric constant.

13. The processing method of the terahertz metamaterial according to claim 1, wherein a value range of a dielectric constant of the substrate is between 2.8 to 4.2, a value range of a loss angle tangent of the substrate is between 0.0048 to 0.0072, and a value range of a thickness of the substrate is between 60 μm to 90 μm.

14. The processing method of the terahertz metamaterial according to claim 1, wherein a value range of a dielectric constant of the substrate is between 3.44 to 5.16, a value range of a loss angle tangent of the substrate is between 0.0032 to 0.0048, and a value range of a thickness of the substrate is between 32 μm to 48 μm.

15. The processing method of the terahertz metamaterial according to claim 8, wherein a factor of the processing method of the terahertz metamaterial that affects the electromagnetic modulation function on the terahertz band comprises at least one of the following:
a size of the electromagnetic loss resonant ring structure;
square resistance of the electromagnetic loss resonant ring structure; or
a periodical arrangement manner of the plurality of electromagnetic loss resonant ring structures on the substrate.

16. The processing method of the terahertz metamaterial according to claim 1, wherein the electromagnetic loss resonant ring structure comprises two side edges that are parallel and symmetrical to each other and a bottom edge that connects the two side edges.

17. The processing method of the terahertz metamaterial according to claim 16, wherein a value range of a length of the side edge is between 180 μm to 220 μm, a value range of a width of the side edge is between 40 μm to 60 μm, a distance between the two side edges is between 180 μm to 220 μm, and a value range of a length of the bottom edge is between 240 μm to 360 μm.
